(19) United States
(12) Patent Application Publication
(10) Pub. No.: US 2023/0284420 A1
(43) Pub. Date: Sep. 7, 2023

(54) ELECTRONIC DEVICE

(71) Applicant: DENSO TEN Limited, Kobe-shi (JP)

(72) Inventors: Naoki MIYAZAKI, Kobe (JP); Satoshi FUKAMACHI, Kobe (JP)

(73) Assignee: DENSO TEN Limited, Kobe-shi (JP)

(21) Appl. No.: 18/072,843

(22) Filed: Dec. 1, 2022

(30) Foreign Application Priority Data
Mar. 7, 2022 (JP) 2022-034838

(51) Int. Cl. H05K 7/20; H05K 1/18; H05K 7/14

(52) U.S. Cl. CPC H05K 7/20409; H05K 1/181; H05K 7/1427; H05K 7/20845

(57) ABSTRACT

An electronic device according to an embodiment includes a substrate, a first electric part, a second electric part, a chassis, and heat radiating fins. The first electric part is mounted on the substrate. The second electric part is mounted on the substrate, the second electric part having a height that is smaller than a height of the first electric part. The chassis houses therein the substrate, the first electric part, and the second electric part. Heat radiating fins protruding from an outer surface of the chassis. The heat radiating fins continuously extend from a side of the second electric part to a side of the first electric part. A portion of the outer surface of the chassis between the first electric part and the second electric part is formed in a slope.

### CROSS-REFERENCE TO RELATED APPLICATION

This application is based upon and claims the benefit of priority of the prior Japanese Patent Application No. 2022-034838, filed on Mar. 7, 2022, the entire contents of which are incorporated herein by reference.

### FIELD

The embodiment discussed herein is directed to an electronic device.

### BACKGROUND

Conventionally, for example, in a case where a short electronic part and a tall electronic part are mounted on the same substrate in an electronic device provided in a vehicle, a height of a product chassis is decided by the tall electronic part. In such a kind of electronic device, there has been a technology in which a short electronic part and a tall electronic part are separately arranged, and heat radiating fins are provided according to heating value of the respective electronic parts (see Japanese Patent No. 6222125, for example).

However, in the conventional technology, there has been a room for improvement in increasing a heat radiating effect.

### SUMMARY

In order to solve the above-mentioned problem to achieve an object, an electronic device according to an embodiment includes a substrate, a first electric part, a second electric part, a chassis, and heat radiating fins. The first electric part is mounted on the substrate. The second electric part is mounted on the substrate, the second electric part having a height that is smaller than a height of the first electric part. The chassis houses therein the substrate, the first electric part, and the second electric part. Heat radiating fins protruding from an outer surface of the chassis. The heat radiating fins continuously extend from a side of the second electric part to a side of the first electric part. A portion of the outer surface of the chassis between the first electric part and the second electric part is formed in a slope.

### BRIEF DESCRIPTION OF DRAWING(S)

FIG. 1 is a diagram illustrating a mount position of an electronic device according to an embodiment;

FIG. 2 is a perspective view illustrating the exterior of the electronic device according to the embodiment;

FIG. 3 is an upward view (from Y-axis negative side) illustrating the electronic device;

FIG. 4 is a cross-sectional view illustrating the electronic device;

FIG. 5 is a diagram illustrating the electronic device viewed from an X-axis positive side; and

FIG. 6 is a cross-sectional view illustrating the electronic device.

### DESCRIPTION OF EMBODIMENTS

Hereinafter, an embodiment of an electronic device according to the present application will be described in detail with reference to the accompanying drawings. The present disclosure is not limited to the embodiment described in the following.

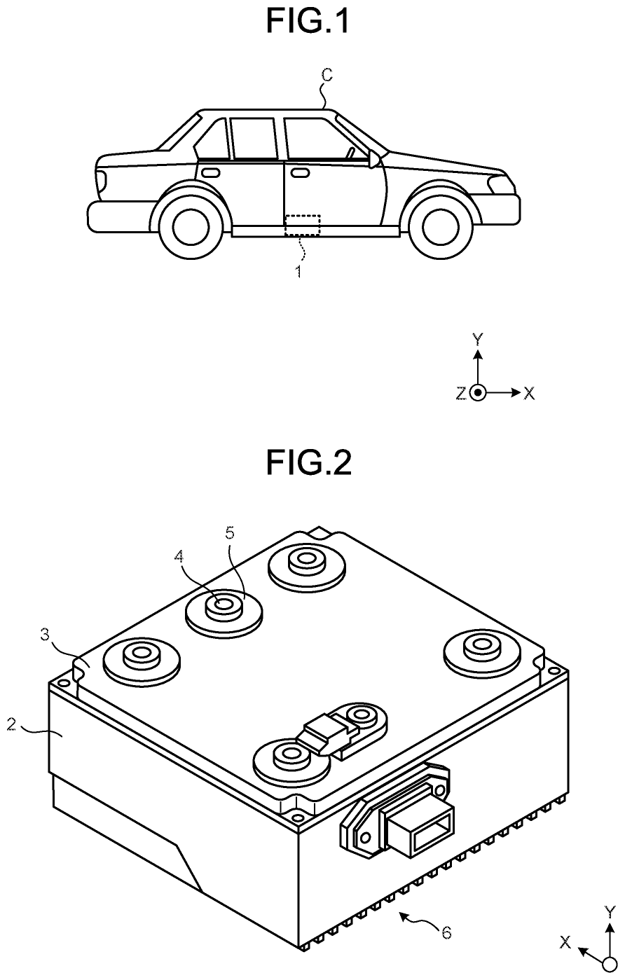

FIG. 1 is a diagram illustrating a mount position of an electronic device according to the embodiment. As illustrated in FIG. 1, an electronic device 1 according to the embodiment is provided in a vehicle C. For example, the electronic device 1 is an inverter that supplies electric power to a drive motor provided in the vehicle C, and is arranged in a bottom part in the outside of the vehicle C, for example. For another example of the mount position, an engine compartment may be employed, which is corresponding to the outside of the vehicle. In other words, the electronic device 1 is arranged in a region that is outside of an enclosed passenger-compartment space and into which outside air flows from the outside. Note that the electronic device 1 may be arranged in a state where the electronic device 1 is exposed to the outside of the vehicle C.

In the following drawings including FIG. 1, a three-axis orthogonal coordinate system is illustrated. Directions that are pointed by respective arrowheads correspond to positive sides, and further directions reverse to the directions that are pointed by the respective arrowheads correspond to negative sides. Specifically, an X-axis corresponds to an advancing direction (front-back direction) of the vehicle C, a positive side thereof is prescribed as the front, and a negative side thereof is prescribed as the rear. A Y-axis corresponds to a vehicle-height direction of the vehicle C, a positive side thereof is prescribed as the upward, and a negative side thereof is prescribed as the downward. Note that any side of the Y-axis may be prescribed as the upward, for example, the positive side thereof may be prescribed as the downward and further the negative side thereof is prescribed as the upward. A Z-axis corresponds a width direction of the vehicle C, a positive side thereof is prescribed as the right side of the vehicle, and a negative side thereof is prescribed as the left side of the vehicle. In FIG. 2 and the following drawings, the Z-axis is not indicated in some cases, and this case means that a direction of positive or negative of the Z-axis does not matter.

Next, FIG. 2 is a perspective view illustrating the exterior of the electronic device 1 according to the embodiment. As illustrated in FIG. 2, the electronic device 1 according to the embodiment has an exterior shape of a substantially rectangular parallelepiped. As illustrated in FIG. 2, the electronic device 1 includes a chassis 2, a lid part 3, bus bars 4, grommets 5, and heat radiating fins 6. Note that other configurations such as an inner configuration of the electronic device 1 will be mentioned later.

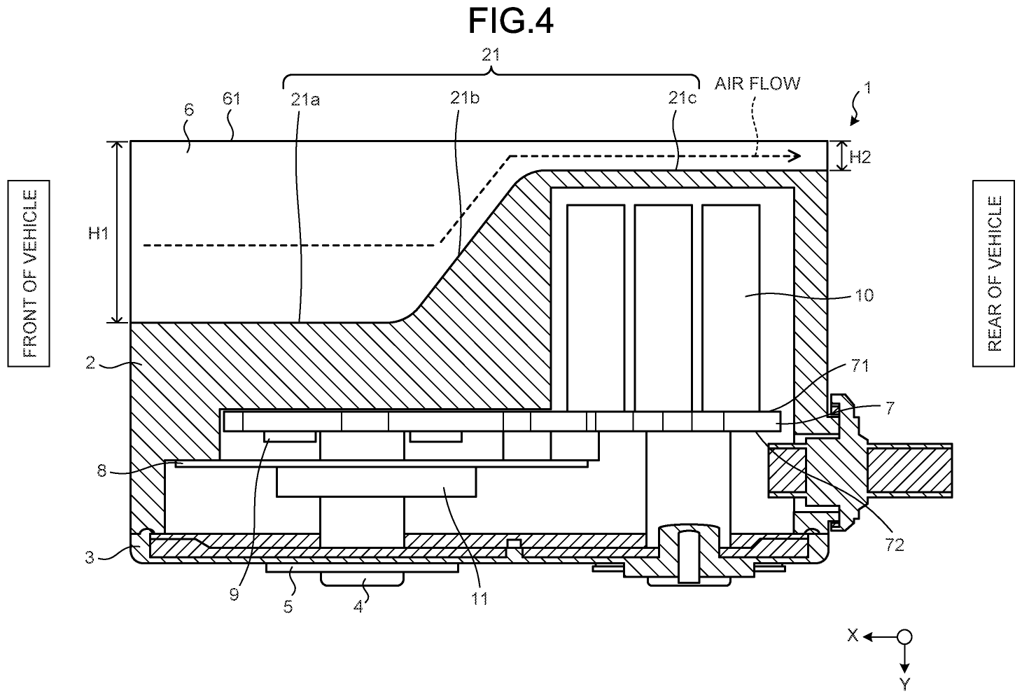

The chassis 2 houses therein various parts such as electronic parts related to the electronic device 1. An internal structure of the chassis 2 will be mentioned later with reference to FIG. 4. The chassis 2 has an opening in an upper side (Y-axis positive side) thereof, and the opening is covered by the lid part 3.

The chassis 2 includes the plurality of heat radiating fins 6 that functions as a heatsink in a lower side (Y-axis negative side) thereof. The heat radiating fins 6 constitute a heat radiating member that protrudes from an outer surface 21 (see FIG. 4) of the chassis 2 so as to radiate heat, to the outside, which is generated from electronic parts housed in the chassis 2.

In the present disclosure, in order to increase air flow between the plurality of heat radiating fins 6, a portion of the outer surface 21 of the chassis 2 is sloped, details thereof will be mentioned later with reference to FIG. 4.

The lid part 3 functions as a lid that closes an opening of the chassis 2. The lid part 3 closes the opening of the chassis 2 so as to prevent entry of an extraneous matter (moisture, dirt, dust, and the like) into an inner part of the chassis 2. Note that in the present disclosure, the chassis 2 and the lid part 3 may be collectively referred to as the chassis 2.

The bus bar 4 is an electric conductive member that causes current generated by the electronic device 1 to flow to a drive motor provided in the vehicle C, and is configured such that the bus bar 4 protrudes from a hole part provided in the lid part 3 (chassis 2) through the hole part from an inner part of the chassis 2. In an inner part of the chassis 2, the bus bar 4 is mounted on a substrate 7 (see FIG. 4).

The grommet 5 is interposed between the chassis 2 (lid part 3) and the bus bar 4 so as to electrically insulate the bus bar 4 from the chassis 2, and prevents entry of an extraneous matter (moisture, dirt, dust, and the like) into an inner part of the chassis 2. The grommet 5 is an elastic member made of resin material or the like, for example.

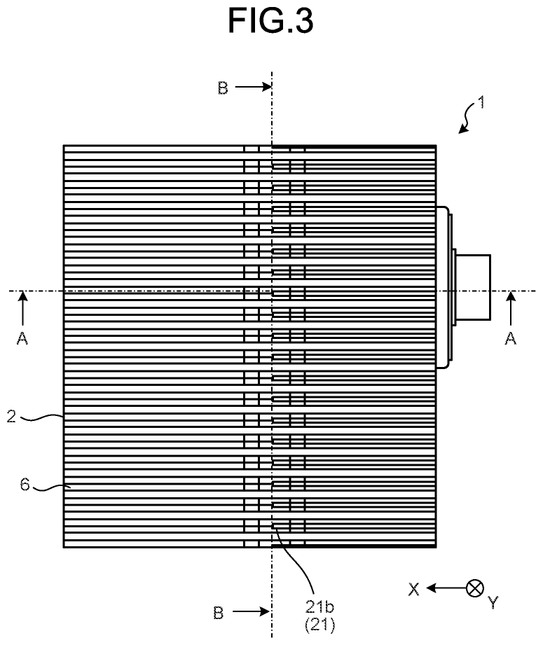

Next, a configuration of the electronic device 1 will be further explained with reference to FIG. 3. FIG. 3 is an upward view (from Y-axis negative side) illustrating the electronic device 1. FIG. 4 is a cross-sectional view illustrating the electronic device 1. The cross-sectional view illustrated in FIG. 4 indicates a cross section taken along a line A-A illustrated in FIG. 3.

As illustrated in FIG. 3, the heat radiating fins 6 are arranged over whole of a lower surface (Y-axis negative side) of the chassis 2. Specifically, each of the heat radiating fins 6 extends in an X-axis direction of the chassis 2. In other words, the heat radiating fins 6 extend along an advancing direction of the vehicle C. The plurality of heat radiating fins 6 is arrayed at equal intervals in a vehicle-width direction that is a Z-axis (not illustrated) direction. Additionally, a shape of the heat radiating fin 6 is not limited to wall-shaped as long as an exposure rate to air for improving a heat radiating property is increased, and thus the columnar heat radiating fins 6 may be aligned along an advancing direction of the vehicle C.

A part of the outer surface 21 of the chassis 2, from which the heat radiating fins 6 protrudes, is formed to be a slope 21b, and details thereof will be mentioned later with reference to FIG. 4.

Next, a cross-section of the electronic device 1 will be explained with reference to FIG. 4. FIG. 4 is a cross-sectional view illustrating the electronic device 1. The cross-sectional view in FIG. 4 indicates a cross-section of the electronic device 1 taken along the line A-A illustrated in FIG. 3.

As illustrated in FIG. 4, the electronic device 1 further includes the first substrate 7, a second substrate 8, a short part 9 (second electric part), a tall part 10 (first electric part), and an electric-current sensor 11 in addition to the above-mentioned chassis 2, the lid part 3, the bus bar 4, the grommet 5, and the heat radiating fins 6.

The first substrate 7 is a power substrate, and the second substrate 8 is a control-system substrate. The power substrate means a substrate through which large current flows, and a power part of e.g., a power integrated circuit (IC) such as a switching element that causes large current to flow into a load, is mounted thereon. Commonly, heating value of a power IC is large and thus is mounted on a power substrate, and is not mounted on a control-system substrate. The control-system substrate is a control board on which electronic parts related to a control circuit are mounted.

The short part 9 and the tall part 10, which are power parts, are electronic parts that are mounted on the first substrate 7. Compared with the tall part 10, the short part 9 has a lower part height (length in Y-axis direction illustrated in FIG. 4), and has a larger heating value. For example, the short part 9 is a transistor such as a Metal-Oxide-Semiconductor Field-Effect Transistor (MOSFET), and the tall part 10 is a capacitor.

The short part 9 and the tall part 10 are mounted on respective different mount surfaces of the first substrate 7. In the example illustrated in FIG. 4, the tall part 10 is mounted on a first surface 71 that is one of principal surfaces of the first substrate 7, and the short part 9 is mounted on a second surface 72 that is the other of the principal surfaces of the first substrate 7. In FIG. 4, an example is exemplified in which the short part 9 is mounted on the second surface 72 and further the tall part 10 is mounted on the first surface 71; however, the short part 9 may be mounted on the first surface 71 or the second surface 72, and thus the short part 9 and the tall part 10 may be mounted on the first surface 71. The heat radiating fin 6 protrudes from a wall surface of the chassis 2, which faces the first surface 71 of the substrate 7. In other words, the heat radiating fin 6 is arranged not on the second surface 72 but on a side of the first surface 71. In a case where the short part 9 is mounted on the second surface 72, the short part 9 is absent on the first surface 71, and thus the chassis 2 and the substrate 7 are allowed to be in contact with each other, so that it is possible to efficiently dissipate heat of the substrate 7 via the chassis 2. In this case, the first surface 71 and the chassis 2 may be in contact with each other via a heat dissipation material (e.g., heat dissipation gel). In a case where the short part 9 is mounted on the first surface 71, a structure can be employed in which the chassis 2 and the short part 9 are in contact with each other, so that heat generated by the short part 9 can be efficiently dissipated into the chassis 2. Note that also in this case, a heat dissipation material may be arranged between the short part 9 and the chassis 2.

The electric-current sensor 11 is mounted on the second substrate 8 so as to detect current flowing through the bus bar 4. Specifically, the bus bar 4 penetrates through the second substrate 8 and is mounted on the second surface 72 of the first substrate 7, and the electric-current sensor 11 is arranged at a penetration part of the bus bar 4 in the second substrate 8.

In the present disclosure, the above-mentioned heat radiating fin 6 of the electronic device 1 extends from a side of the tall part 10 toward a side of the short part 9 (along X-axis direction). In the heat radiating fin 6 is arranged, a portion of the outer surface 21 between the tall part 10 and the short part 9 is formed in the slope 21b.

Specifically, a first flat surface 21a, the slope 21b, and a second flat surface 21c are continuously connected along an X-axis direction so as to constitute the outer surface 21 on which the heat radiating fin 6 is arranged. The slope 21b is a rising slope that rises up from the front toward the rear in an advancing direction of the vehicle C. Namely, the slope 21b is sloped such that a distance thereto from the first substrate 7 increases as a position goes from the front toward the rear in an advancing direction of the vehicle C. In other words, the chassis 2 is attached such that the short part 9 is arranged to direct the front of a vehicle. Thus, wind caused by travelling of the vehicle C directly hits the short part 9 whose heating value is large, so that it is possible to increase a heat radiating effect.

As described above, in the electronic device 1 according to the embodiment, the slope 21b is provided to the outer surface 21 of the heat radiating fin 6, for example, wind from the front of a vehicle flows toward the rear of the vehicle along the slope 21b, so that it is possible to improve air flow between the heat radiating fins 6, and further to improve a heat radiating effect.

Moreover, the slope 21b is formed in a rising slope such that a distance thereto from the first substrate 7 increases as a position goes from the front toward the rear in the advancing direction, so that it is possible to reduce a part in which air remains between the heat radiating fins 6. If the heat radiating fin 6 does not include the slope 21b so as to extend from the first flat surface 21a to the second flat surface 21c, air between the heat radiating fins 6 hits a level difference caused by difference in height between the first flat surface 21a and the second flat surface 21c, and thus air remains at the level difference. Thus, the slope 21b is formed in a rising slope such that a distance thereto from the first substrate 7 increases as a position goes from the front toward the rear in the advancing direction, so that it is possible to reduce a part between the heat radiating fins 6 in which air remains. Thus, it is possible to improve air flow, and further to improve a heat radiating effect.

As illustrated in FIG. 4, the tall part 10 and the short part 9 are arranged on respective different mount surfaces of the first substrate 7, for example, a space close to the second surface 72 on which the short part 9 is mounted, is able to be short in accordance with a height of the short part 9. In other words, it is possible to miniaturize the electronic device 1.

As illustrated in FIG. 4, in the heat radiating fin 6, a height H1 from the outer surface 21 (first flat surface 21a) close to the short part 9 up to a leading end 61 is set to be higher than a height H2 the outer surface 21 close to the short part 9 up to the leading end 61. In other words, in the heat radiating fin 6, a position of the leading end 61 is formed to be linear along the X-axis direction, and a distance (in this case, corresponding to depth of channel between heat radiating fins 6) from the leading end 61 to the outer surface 21 on a side of the short part 9 is set to be longer than that on a side of the tall part 10.

In other words, heat radiating efficiently on a side of the short part 9 is set to be higher than that on a side of the tall part 10. This is because heating value of the short part 9 is larger than that of the tall part 10. Thus, it is possible to efficiently radiate heat generated by the short part 9, and the heat radiating fin 6 close to the tall part 10 whose heating value is small is set to be small, so that it is further possible to realize miniaturization of the electronic device 1.

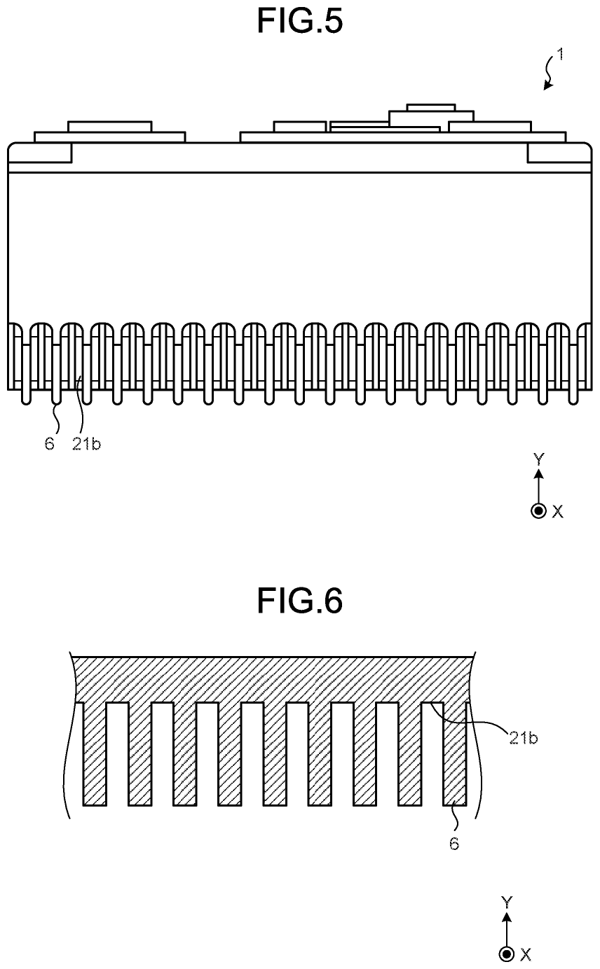

Next, relation between the heat radiating fins 6 and the slopes 21b will be explained with reference to FIGS. 5 and 6. FIG. 5 is a diagram illustrating the electronic device 1 viewed from an X-axis positive side. FIG. 6 is a cross-sectional view illustrating the electronic device 1. The cross-sectional view illustrated in FIG. 6 indicates a cross-section taken along a line B-B illustrated in FIG. 3.

As illustrated in FIG. 5, the heat radiating fins 6 protrude straight along a Y-axis negative direction. In other words, the heat radiating fins 6 protrude straight toward the underneath of the vehicle C.

As illustrated in FIG. 6, the heat radiating fins 6 protrude in a direction perpendicular to the slope 21b. Thus, air is capable of flowing through space between the heat radiating fins 6 without remaining therein.

As described above, the electronic device 1 according to the embodiment includes the substrate 7, the tall part 10, the short part 9, and the heat radiating fins 6. The tall part 10 is mounted on the substrate 7. The short part 9 is mounted on the substrate 7. The heat radiating fins 6 protrude from the outer surface 21 of the chassis 2, the chassis 2 housing therein the substrate 7, the tall part 10, and the short part 9. The heat radiating fins 6 continuously extend from a side of the tall part 10 to a side of the short part 9, and a portion of the outer surface 21 between the tall part 10 and the short part 9 is formed in the slope 21b. Thus, it is possible to improve air flow between the heat radiating fins 6, and further to improve a heat radiating effect.

According to the present disclosure, it is possible to increase a heat radiating effect.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An electronic device comprising:
a substrate;
a first electric part that is mounted on the substrate;
a second electric part that is mounted on the substrate, the second electric part having a height that is smaller than a height of the first electric part;
a chassis that houses therein the substrate, the first electric part, and the second electric part; and
heat radiating fins protruding from an outer surface of the chassis, wherein
the heat radiating fins continuously extend from a side of the second electric part to a side of the first electric part, and
a portion of the outer surface of the chassis between the first electric part and the second electric part is formed in a slope.

2. The electronic device according to claim 1, wherein
the first electric part is arranged on a first surface that is one of surfaces of the substrate,
the second electric part is arranged on a second surface that is another of the surfaces of the substrate; and
the heat radiating fins are arranged on a side of the first surface.

3. The electronic device according to claim 1, wherein
the heat radiating fins extend in an advancing direction of the vehicle, and
the slope is sloped such that a distance thereto from the substrate increases as a position goes from a front toward a rear in the advancing direction.

4. The electronic device according to claim 1, wherein
the second electric part is arranged on the first surface to be in contact with the chassis.

5. The electronic device according to claim 1, wherein
in the heat radiating fins, a height from the outer surface to a leading end on a side of the second electric part is larger than a height from the outer surface to the leading end on a side of the first electric part.

6. The electronic device according to claim 1, wherein
the first electric part includes a capacitor, and
the second electric part includes a transistor.
